(19) United States
(12) Patent Application Publication
(10) Pub. No.: US 2004/0245589 A1
(43) Pub. Date: Dec. 9, 2004

(54) Substrate structure for a photosensitive chip package

(76) Inventors: Jackson Hsieh, Hsinchu Hsien (TW); Jichen Wu, Hsinchu Hsien (TW); Worrell Tsai, Hsinchu Hsien (TW); Abnet Chen, Hsinchu Hsien (TW)

Correspondence Address: PRO-TECHTOR INTERNATIONAL, 20775 Norada Court, Saratoga, CA, 95070-3018, US

(21) Appl. No.: 10/456,011

(22) Filed: Jun. 5, 2003

(51) Int. Cl. H01L 31/0203

(52) U.S. Cl. 257/433

(57) ABSTRACT

A substrate structure for a photosensitive chip package includes a plurality of leadframes, which are arranged in a matrix, and a molded resin. Each of the leadframes have a first board and a second board located on a height different from that of the first board, and a chamber is defined upper a central of the plurality of leadframes. And the molded resin is for encapsulating the leadframes, and forming an upper surface and a lower surface, wherein the first boards of the leadframes are exposed from the upper surface of the molded resin.

### BACKGROUND OF THE INVENTION

1. Field of the Invention

The present invention relates to a substrate structure for a photosensitive chip package, and more particularly to a photosensitive chip package having a reduced manufacturing cost and package volume.

2. Description of the Related Art

Referring to FIG. 1, a conventional image sensor includes a plurality of leadframes 10, a frame layer 16, a photosensitive chip 18, wires 19 and a transparent layer 22. The plurality of leadframes 10 arranged in matrix, each of the leadframes 10 having a first board 12 and a second board 14 located on a height different from the second board 14. A frame layer 16 for encapsulating the leadframes 10, and a chamber 20 being defined for mounting the photosensitive chip, wherein the first board 12 and second board 14 are exposed from the frame layer 16. The photosensitive chip 18 is arranged within the chamber 20 and is electrically connected to the second board 14 of the leadframes. The transparent layer 22 is disposed on the upper surface of the frame layer 16. Furthermore, the photosensitive chip 18 may receive optical signals passing through the transparent layer 22.

According to the above-mentioned structure, the invention has following advantage.

1. The transparent layer 22 is disposed on the upper surface of the frame layer 16. Thus, the volume of the package may not be reduced.

### SUMMARY OF THE INVENTION

An object of the present invention is to provide a substrate structure for a photosensitive chip package, and the substrate structure may advantageously reduce the volume of the package.

Another object of the present invention is to provide a substrate structure for a photosensitive chip package, which may be assembled easily and has a reduced manufacturing cost.

To achieve the above-mentioned object, the present invention provides a substrate structure for a photosensitive chip package including a plurality of leadframes arranged in a matrix and a molded resin. Each of the leadframes having a first board and a second board located on a height different from that of the first board, and a chamber being defined upper a central of said a plurality of leadframes, and a molded-resin for encapsulating the leadframes, and forming a upper surface and a lower surface, wherein the first boards of the leadframes are exposed from the upper surface of the molded resin.

Furthermore, the transparent layer of the image sensor may be mount on the first board of the leadframes, the package may be advantageously reduced the volume of the package, and may be assembled easily and has a reduced manufacturing cost.

### BRIEF DESCRIPTION OF THE DRAWINGS

FIG. 1 is a schematic illustration showing a conventional image sensor package.

FIG. 2 is a cross-sectional view showing a substrate structure for a photosensitive chip package of the present invention.

FIG. 3 is a cross-sectional view showing the leadframes of the present invention.

FIG. 4 is a first schematic illustration showing a substrate structure for a photosensitive chip package of present the invention.

FIG. 5 is a second schematic illustration showing a substrate structure for a photosensitive chip package of the present invention.

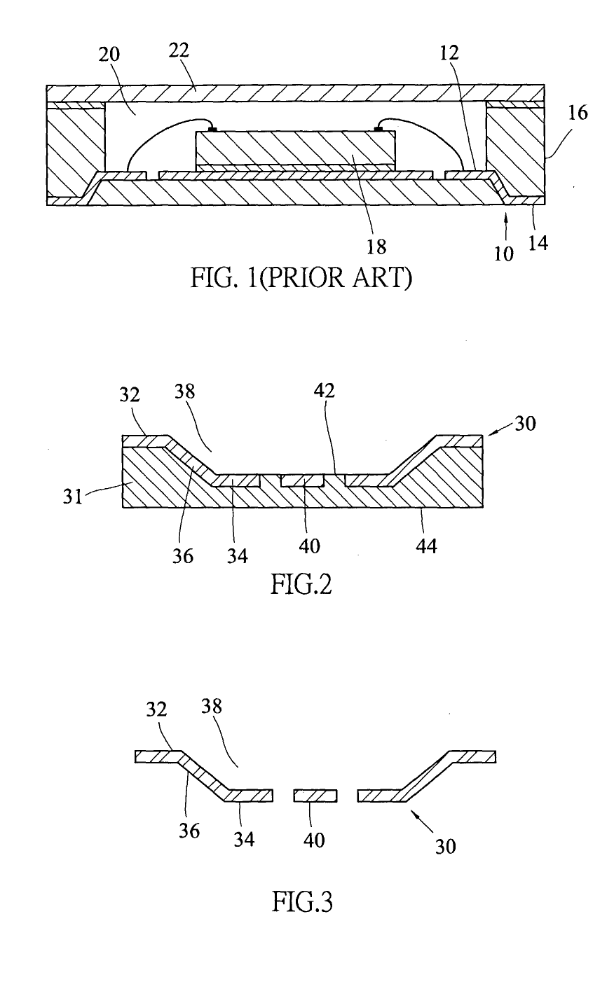

### DETAILED DESCRIPTION OF THE INVENTION

Referring to FIG. 2 is a substrate structure for photosensitive chip package of the present invention includes plurality of leadframes 30 arranged in matrix, a molded resin 31.

Please referring to FIG. 3 is a cross-sectional view showing the leadframes of the invention.

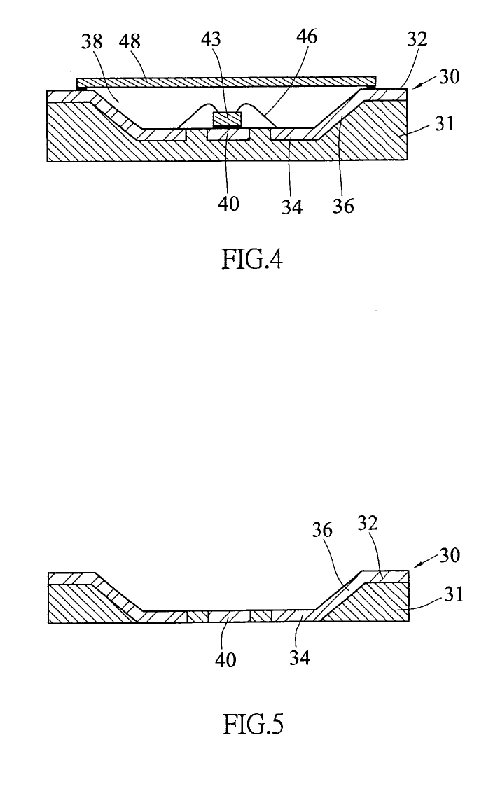

The plurality of leadframes 30 are arranged in matrix, each of leadframes 30 have a first board 32 and a second board 34 located on a height different from that of the first board 32. A chamber 38 is defined upper a central of the leadframe 30, and a middle board 40 is arranged within the internal of the chamber 38, then, the photosensitive chip 43 is mounted to the middle board 40, and is located within the chamber 38 (as shown is FIG. 4).

The molded resin 31 is made of industrial plastic by way of injection molding to encapsulate leadframes 30, and has a upper surface 42 and a lower surface 44, wherein the first boards 32 of the leadframes 30 are exposed from the upper surface 42 of the molded resin 31, the second board 34 of the leadframes 30 are exposed from the upper surface 42 of the molded resin 31, by way of wire 46 to electrically connected to the photosensitive chip 43 (as shown in FIG. 4).

Please referring to FIG. 4 is a schematic illustration showing a substrate structure for a photosensitive chip package of the present invention.

The photosensitive chip 42 is arranged onto the middle board 40 of the leadframes 30, by way of wires 46 electrically connected to the second board 34 of the leadframes 30, thus, the signals from the photosensitive chip 43 may be transmitted to the leadframes 30. The transparent layer 48 is mounted to the first board 32 of the leadframes 30, thus, the photosensitive chip 43 is covered, then, the photosensitive chip 43 may be received optical signals passing through the transparent layer 48.

Referring to FIG. 5 is a second schematic illustration showing a substrate structure for a photosensitive chip package of present the invention.

Wherein the second board 34 and middle board 40 of the leadframes 30 are exposed from the lower surface 44 of the molded layer 31, therefore, the lower surface of second board 34 may be electrically connected to a printed circuit board. Thus, the photosensitive chip 43 may enhance the effects of dissipation head

To sum up, the present invent has the following advantages.

1. Since the leadframes 30 are formed with a chamber 38, and the photosensitive chip 33 is located within the chamber 38 so as to the volume the package can be reduced.

2. Since the printed circuit board 39 is directly covered over the first board 32 of the leadframes 30, on frame layer has to be provided. Thus, the manufacturing processes may be simplified and manufacturing cost may be reduced.

While present the invention has been described by way of an example and in terms of a preferred embodiment, it is to be understood that the invention is not limited to the disclosed embodiment. To the contrary, it is intended to cover various modifications. Therefore, the scope of the appended claims should be accorded the broadest interpretation so as to encompass all such modifications.

What is claimed is:

1. A substrate structure for a photosensitive chip package, comprising:
a plurality of leadframes arranged in a matrix, each of the leadframes having a first board and a second board located on a height different from that of the first board, and a chamber being defined upper a central of the plurality of leadframes; and
a molded resin for encapsulating the leadframes and forming a upper surface and a lower surface, wherein the first boards of the leadframes being exposed from the upper surface of the molded resin, the second board of the leadframes being exposed from the upper surface of the molded resin.

2. The substrate structure according to claim 1, further comprising a middle board is arranged on the chamber of the leadframes, wherein the photosensitive chip is placed on the middle board.

3. The substrate structure according to claim 2, wherein the lower surface of the middle board is exposed from the lower surface of the molded resin.

4. The substrate structure according to claim 1, wherein the lower surface of the second boards are exposed from the lower surface of the molded resin.

5. The substrate structure according to claim 1, wherein the molded resin is for encapsulating the leadframes by way of injecting molding.

6. The substrate structure according to claim 1, further comprising a plurality of wires are for electrically connecting the photosensitive chip to the second board of the leadframe.
